(19) United States
(12) Patent Application Publication
(10) Pub. No.: US 2011/0227132 A1
(43) Pub. Date: Sep. 22, 2011

(54) FIELD-EFFECT TRANSISTOR

(75) Inventors: Yoshiharu ANDA, Osaka (JP); Hidetoshi ISHIDA, Osaka (JP); Tetsuzo UEDA, Osaka (JP)

(73) Assignee: PANASONIC CORPORATION, Osaka (JP)

(21) Appl. No.: 13/118,945

(22) Filed: May 31, 2011

Related U.S. Application Data
(63) Continuation of application No. PCT/JP2009/006038, filed on Nov. 12, 2009.

(30) Foreign Application Priority Data
Dec. 5, 2008 (JP) 2008-311416

(51) Int. Cl. H01L 29/205

(52) U.S. Cl. 257/192; 257/E29.091

(57) ABSTRACT

The present invention has as an object to provide a FET having low on-resistance. The FET according to the present invention includes: first nitride semiconductor layer; a second nitride semiconductor layer formed on the first nitride semiconductor layer and having a higher band gap energy than the first nitride semiconductor layer; a third nitride semiconductor layer formed on the second nitride semiconductor layer; a fourth nitride semiconductor layer formed on the third nitride semiconductor layer and having a higher band gap energy than the third nitride semiconductor layer. A channel is formed in a heterojunction interface between the first nitride semiconductor layer and the second nitride semiconductor layer.

### CROSS REFERENCE TO RELATED APPLICATION

This is a continuation application of PCT application No. PCT/JP2009/006038 filed on Nov. 12, 2009, designating the United States of America.

### BACKGROUND OF THE INVENTION

(1) Field of the Invention

The present invention relates to field-effect transistors, and particularly relates to a field-effect transistor made of a group-III nitride semiconductor.

(2) Description of the Related Art

Group-III nitride semiconductors represented by gallium nitride (GaN) semiconductors have a wide band gap, high breakdown field, and high saturated electron velocity which exceed those of semiconductors made of silicon or gallium arsenide. Due to this physical advantage, field-effect transistors (FETs) using a group-III nitride semiconductor show much potential as next-generation radio frequency devices or high-power switching devices, and are thus the subject of widespread research and development.

Although the aforementioned FETs are required to achieve both high breakdown voltage and low on-resistance, there is generally a trade-off relationship between both characteristics when the same material is used. In addition, a high-power switching device requires a normally-off FET, and thus gate-source parasitic resistance and gate-drain parasitic resistance tend to increase even further. Furthermore, it is known that trap levels are present in high density in the surface of the group-III nitride semiconductor, and that the trap levels caught during a high-speed switching operation are unable to keep up with the switching and thus a current collapse in which drain current decreases occurs.

The FETs disclosed in, for example, Japanese Unexamined Patent Application Publication No. 2002-359256 (Patent Reference 1) and Japanese Unexamined Patent Application Publication No. 2008-211172 (Patent Reference 2) are known as conventional FETs using a nitride semiconductor. FIG. 8 is a cross-sectional view of a structure of the FET in Patent Reference 1.

As shown in FIG. 8, in the FET in Patent Reference 1, a carrier travel layer 802 and a carrier supply layer 803 are provided on a substrate 801, and a GaN protective layer 804 is additionally provided on a top plane of the carrier supply layer 803. In addition, the region between a gate electrode 806 and a source electrode 808 and the gap between the gate electrode 806 and a drain electrode 807 in the surface of the GaN protective layer 804 is covered by a protective layer 805 made of silicon nitride (SiN). With this, the surface levels of the group-III nitride semiconductor can be reduced, and current collapses caused by the surface trap levels at the flanks of the gate electrode 806 can be reduced.

### SUMMARY OF THE INVENTION

However, with the conventional FETs using a group-III nitride semiconductor, on-resistance is not sufficiently low and further reduction of on-resistance is required. Furthermore, the breakdown voltage of an element is determined by the distance between the gate electrode and the drain electrode, and, although breakdown voltage improves by increasing such distance, gate-drain parasitic resistance increases and on-resistance increases.

Here, on-resistance leads to power loss in either a radio frequency device or a high power switching device, and thus it is preferable that on-resistance be sufficiently low. In the future, further reduction of on-resistance is necessary for increasing FET performance. Moreover, improving the device structure is effective in the reduction of on-resistance.

Furthermore, in a normally-off FET, the gate-source parasitic resistance and gate-drain parasitic resistance have a tendency to increase, and, although the FET in Patent Reference 1 takes into account the increase in parasitic resistance by suppressing the effects of surface levels, further reduction in resistance is required.

In view of this, the present invention was conceived in order to solve the aforementioned problem and has as an object to provide a field-effect transistor having low on-resistance.

In order to achieve the aforementioned object, the field-effect transistor according to an aspect of the present invention includes: a first nitride semiconductor layer; a second nitride semiconductor layer formed on the first nitride semiconductor layer and having a band gap energy that is higher than a band gap energy of the first nitride semiconductor layer; a third nitride semiconductor layer formed on the second nitride semiconductor layer; and a fourth nitride semiconductor layer formed on the third nitride semiconductor layer and having a band gap energy that is higher than a band gap energy of the third nitride semiconductor layer, wherein a channel is formed in a heterojunction interface between the first nitride semiconductor layer and the second nitride semiconductor layer.

According to this configuration, a channel is formed, not only in the heterojunction interface between the first nitride semiconductor layer and the second nitride semiconductor layer, but also in the heterojunction interface between the third nitride semiconductor layer and the fourth nitride semiconductor layer. In other words, in addition to the two-dimensional electron gas formed in the conventional channel, a two-dimensional gas is additionally formed in the surface side. Therefore, sheet resistance can be reduced, and on-resistance can be reduced.

Furthermore, since the channel is distanced from the semiconductor layer closest to the surface side, compared to that in the conventional FET, the effects of surface levels on the channel can be reduced. As a result, current collapse caused by surface levels can be suppressed.

Furthermore, since two heterojunction interfaces are formed by nitride semiconductors, two-dimensional electron gas is produced in the heterojunction interfaces due to the piezoelectric polarization arising from lattice mismatch and to spontaneous polarization. Therefore, there is no need to add impurities in the forming of the channel, and thus a FET with a high breakdown voltage can be realized.

Here, it is preferable that a gate electrode of the field-effect transistor be formed in a recess provided in the fourth nitride semiconductor layer.

According to this configuration, the channel can be brought closer to the gate electrode while distancing the channel from the semiconductor layer that is in the side closest to the surface of the FET. As a result, controlling the threshold voltage of the gate can be facilitated while suppressing current collapses.

Here, it is preferable that the recess penetrate through a heterojunction interface between the third nitride semiconductor layer and the fourth nitride semiconductor layer. In particular, it is preferable that the recess penetrate through the heterojunction interface between the third nitride semiconductor layer and the fourth nitride semiconductor layer, and reaches a surface of the second nitride semiconductor layer, and the surface of the second nitride semiconductor layer, which is a bottom plane of the recess, be coplanar with as the heterojunction interface between the second nitride semiconductor layer and the third nitride semiconductor layer.

According to this configuration, the threshold voltage of the gate is determined according to the thickness and Al composition ratio of the second nitride semiconductor layer, and thus controlling of the threshold value of the gate can be facilitated. Therefore, it is possible to realize a FET having uniform gate threshold voltage within a wafer.

Furthermore, it is preferable that the field-effect transistor further include an insulating film formed on a bottom plane of the recess.

According to this configuration, it is possible to adopt a metal insulator semiconductor (MIS) structure for the FET so as to suppress the current flowing to the gate and apply a positive bias to the gate electrode, and thus an effective structure, as a normally-off FET, can be realized.

Furthermore, it is preferable that the field-effect transistor further include: a fifth nitride semiconductor layer formed on a bottom plane of the recess; and an insulating film formed between the gate electrode and the fifth nitride semiconductor layer.

According to this configuration, the insulating film can be formed successively with the epitaxial growing of the fifth nitride semiconductor layer within the recess, and thus an insulating film having excellent insulation characteristics can be realized.

Furthermore, it is preferable that the insulating film be made of a stacked structure of silicon nitride and aluminum nitride.

According to this configuration, the insulating film includes AlN which is a good conductor of heat, and thus it is possible to realize a FET that is especially effective particularly for devices that drive a large amount of power.

Furthermore, it is preferable that the insulating film be formed using an atomic layer deposition apparatus.

According to this configuration, improvement of the film properties of the insulating film and excellent control over film-thickness become possible.

Here, it is preferable that a film-thickness of the second nitride semiconductor layer be less than a film-thickness of the fourth nitride semiconductor layer.

According to this configuration, the electrons of the channel in the heterojunction interface between the third nitride semiconductor layer and the fourth nitride semiconductor layer can be effectively guided to the channel in the heterojunction interface between the first nitride semiconductor layer and the second nitride semiconductor layer. As a result, channel resistance can be further reduced, and on-resistance can be reduced. Furthermore, since the film-thickness of the second nitride semiconductor layer directly under the gate electrode can be made thin, it is possible to realize an effective structure for a normally-off FET.

Furthermore, it is preferable that each of a source electrode and a drain electrode of the field-effect transistor be in contact with the heterojunction interface between the first nitride semiconductor layer and the second nitride semiconductor layer and a heterojunction interface between the third nitride semiconductor layer and the fourth nitride semiconductor layer.

According to this configuration, the contact resistance of the source electrode and the drain electrode can be reduced.

According to the present invention, low on-resistance can be realized in a FET made of nitride semiconductors.

### Further Information About Technical Background To This Application

The disclosure of Japanese Patent Application No. 2008-311416 filed on Dec. 5, 2008, including specification, drawings and claims is incorporated herein by reference in its entirety.

The disclosure of PCT application No. PCT/JP2009/006038 filed on Nov. 12, 2009, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a cross-sectional view of a configuration of a FET according to Embodiment 1 of the present embodiment;

FIG. 2 is a diagram showing an energy band of the FET according to Embodiment 1;

FIG. 3A is a diagram showing a FET having a single-channel structure;

FIG. 3B is a diagram showing a FET having a double-channel structure;

FIG. 3C is a diagram showing results of an experiment on the relationship between breakdown voltage and on-resistance in the diode characteristics of a gate electrode and a drain electrode;

FIG. 4 is a cross-sectional view of a configuration of a FET according to Embodiment 2 of the present invention;

FIG. 5 is a cross-sectional view of a configuration of a FET according to embodiment 3 of the present invention;

FIG. 6 is a cross-sectional view of a configuration of a FET according to Embodiment 4 of the present invention:

FIG. 7 is a cross-sectional view of a configuration of a FET according to Embodiment 5 of the present invention; and

FIG. 8 is a cross-sectional view of the structure of a conventional FET.

### DESCRIPTION OF THE PREFERRED EMBODIMENTS

Hereinafter, FETs in the embodiments of the present invention shall be described with reference to the Drawings.

### Embodiment 1

Hereinafter, a configuration of a FET in Embodiment 1 of the present invention and a manufacturing method thereof shall be described.

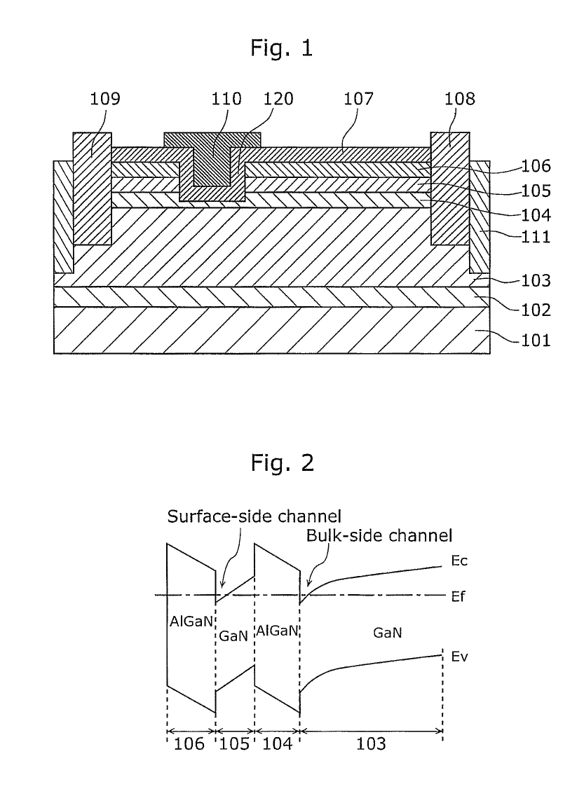

FIG. 1 is a cross-sectional view of a configuration of a display device according to the present embodiment.

The FET includes a substrate 101, a buffer layer 102, a first nitride semiconductor layer 103, a second nitride semiconductor layer 104, a third nitride semiconductor layer 105, a fourth nitride semiconductor layer 106, an insulating film 107, a drain electrode 108, a source electrode 109, a gate electrode 110, and an element separation layer 111.

The substrate 101 is, for example, a sapphire substrate, a SiC substrate, a Si substrate, a GaN substrate, and so on, having a thickness (film-thickness) of between 10 μm to 1000 μm, inclusive.

The buffer layer 102 is made of AlN having a thickness, for example, 100 nm, that depends on the substrate 101, and is formed on the substrate 101.

The first nitride semiconductor layer 103 is made of, for example, 2 μm-thick undoped GaN, and is formed on the buffer layer 102. Here, “undoped” means that impurities are not intentionally introduced.

The second nitride semiconductor layer 104 is formed on the first nitride semiconductor layer 103 and has higher band gap energy than the first nitride semiconductor layer 103. The second nitride semiconductor layer 104 is made of, for example, undoped AlₓGa₁₋ₓN (0<x≦1). For example, the second nitride semiconductor layer 104 is made of 20 nm-thick undoped Al_{0.25}Ga_{0.75}N.

The third nitride semiconductor layer 105 is formed on the second nitride semiconductor layer 104 and has lower band gap energy than the second nitride semiconductor layer 104. The third nitride semiconductor layer 105 is made of, for example, 20 nm-thick undoped GaN.

The fourth nitride semiconductor layer 106 is formed on the third nitride semiconductor layer 105 and has higher band gap energy than the third nitride semiconductor layer 105. The fourth nitride semiconductor layer 106 is made of, for example, undoped Al_{y}Ga_{1-y}N (0<y≦1). For example, the fourth nitride semiconductor layer 106 is made of 25 nm-thick undoped Al_{0.25}Ga_{0.75}N.

A charge of approximately 1×10¹³ cm⁻², for example, is generated in the heterojunction interface between the first nitride semiconductor layer 103 and the second nitride semiconductor layer 104 and in the heterojunction interface between the third nitride semiconductor layer 105 and the fourth nitride semiconductor layer 106 due to spontaneous polarization and piezoelectric polarization, electrons travel through the heterojunction interfaces when the gate is ON, and, in particular, it is possible to significantly reduce resistance in the horizontal direction in the FET.

The drain electrode 108 is formed in a region on one side of the gate electrode 110 and the source electrode 109 is formed in a region on the opposite side of the gate electrode 110, and each of the drain electrode 108 and the source electrode 109 is in contact with the heterojunction interface between the first nitride semiconductor layer 103 and the second nitride semiconductor layer 104 and the heterojunction interface between the third nitride semiconductor layer 105 and the fourth nitride semiconductor layer 106, and is electrically connected to an electron travel region (channel) created in the interface regions. The drain electrode 108 and the source electrode 109 are in contact with the first nitride semiconductor layer 103.

The drain electrode 108 and the source electrode 109 are each made of a stacked structure of Ti and Al for example.

A recess 120 is formed in the second nitride semiconductor layer 104, the third nitride semiconductor layer 105, and the fourth nitride semiconductor layer 106. The recess 120 penetrates through the third nitride semiconductor layer 105 and the fourth nitride semiconductor layer 106, that is, penetrates through the heterojunction interface between the third nitride semiconductor layer 105 and the fourth nitride semiconductor layer 106, and reaches the surface of the second nitride semiconductor layer 104. Then, the gate electrode 110 is formed in the recess 120.

The gate electrode 110 is made of, for example, palladium (Pd), nickel (Ni), and platinum (Pt). It should be noted that the gate electrode 110 may be made of Ti when the material making up the gate electrode 110 does not diffuse into the nitride semiconductor layer due to the insulating film 107.

The insulating film 107 is formed on the bottom plane and lateral planes of the recess 120 and on the surface of the fourth nitride semiconductor layer 106. The insulating film 107 formed on the bottom plane and lateral planes of the recess 120 is interposed between (i) the second nitride semiconductor layer 104, the third nitride semiconductor layer 105, and the fourth nitride semiconductor layer 106, and (ii) the gate electrode 110.

The insulating film 107 is made of, for example, silicon nitride (SiN), silicon oxide (SiO), aluminum nitride (AlN), aluminum oxide (AlO), a stacked structure of SiN and AlN, a stacked structure of SiN and AlO, and so on. When the insulating film 107 is made of SiN or SiO, the insulating film 107 is formed using, for example, a plasma chemical vapor deposition (CVD) method or a low-pressure CVD method. On the other hand, when the insulating film 107 is made of AlN or AlO, the insulating film 107 is formed using, for example, a sputtering method or an atomic layer deposition (ALD) method using an atomic layer deposition apparatus.

The element separation layer 111 is formed, for example, by ion injection of an impurity such as boron (B) into a nitride semiconductor layer, and electrically separates the FET from other elements.

FIG. 2 is a diagram of the energy band of the FET according to the present embodiment.

In the case where the gate bias is zero, a channel (referred to as the bulk-side channel) is formed due to the production of a two-dimensional electron gas in the heterojunction interface between the first nitride semiconductor layer 103 and the second nitride semiconductor layer 104, and a channel (referred to as surface-side channel) is also formed in a surface side due to the production of a two-dimensional electron gas in the heterojunction interface between the third nitride semiconductor layer 105 and the fourth nitride semiconductor layer 106. Since the two channels such a bulk-side channel and surface-side channel are formed, the total channel resistance is reduced. Although there is a potential barrier between these two channels, movement of electrons between these two channels is possible by tunneling, and thus the electrons of the surface-side channel are also contributory as drain current. As such, the on-resistance can be reduced by as much as the amount of reduction in channel resistance. Furthermore, compared to the conventional FET, the bulk-side channel is distanced from the semiconductor layer closest to the surface side of the FET (the fourth nitride semiconductor layer 106 surface), and thus the effects of surface levels on the channel is reduced. As a result, current collapse caused by surface levels can be suppressed.

Here, in order that the electrons of the surface-side channel are more effectively guided to the bulk-side channel, it is preferable that the Al composition ratio of the fourth nitride semiconductor layer 106 be higher than the Al composition ratio of the second nitride semiconductor layer 104, and in addition, it is preferable that the thickness of the fourth nitride semiconductor layer 106 be greater than the thickness of the second nitride semiconductor layer 104. Furthermore, in order to make the film-thickness of the second nitride semiconductor layer 104 directly under the gate electrode 110 thin and realize the normally-off FET, it is preferable that the thickness of the second nitride semiconductor layer 104 be less than the thickness of the fourth nitride semiconductor layer 106.

As described above, according to the FET in the present embodiment, two heterojunction interfaces are formed by stacked structures of GaN/AlGaN/GaN/AlGaN, for example. In addition, two-dimensional electron gas is produced by the piezoelectric polarization arising from lattice mismatch between AlGaN and GaN and by the spontaneous polarization arising from the GaN layer itself. Therefore, since the electron travel layer (channel) formed in the AlGaN/GaN heterojunction interface is provided in a plurality, the on-resistance between the gate electrode 110 and the source electrode 109 and between the gate electrode 110 and the drain electrode 108 can be reduced.

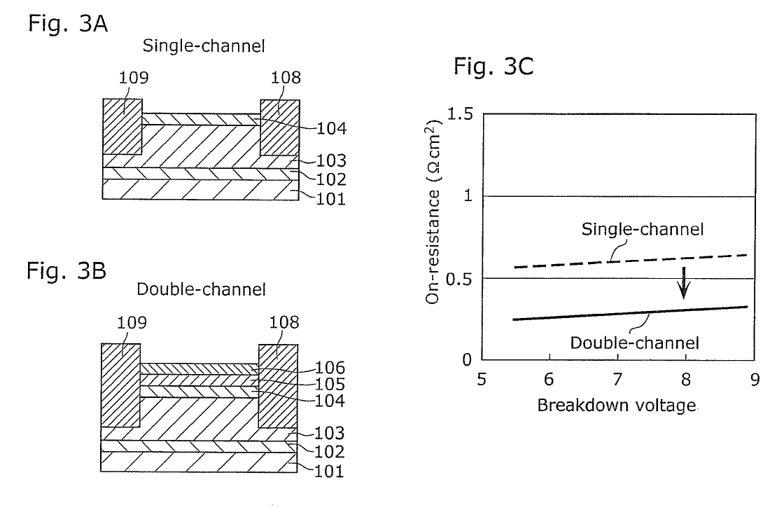

FIG. 3C shows a result of experiments on the relationship between breakdown voltage and on-resistance in the diode characteristics of the gate electrode 110 and the drain electrode 108, for the single-channel structure having one electron travel layer in FIG. 3A and the double-channel structure having two electron travel layers in FIG. 3B.

It can be seen from FIG. 3C that, when breakdown voltage is approximately the same for both structures, on-resistance can be reduced to about half in the double channel structure. Therefore, for example, by using a stacked structure of GaN/AlGaN/GaN/AlGaN, the amount of electrons traveling increases compared to the conventional FET including only one heterojunction interface of GaN/AlGaN, and thus on-resistance can be reduced. By providing this double-channel structure on both sides of the gate electrode 110, the parasitic resistance of the source and drain of the FET can be suppressed to approximately half while maintaining the same breakdown voltage. In particular, although the drain-side is where electrical fields normally concentrate, the breakdown voltage does not deteriorate even when multiple layers of the electron travel layers are provided. At this time, the resistance in the vertical direction of the GaN/AlGaN/GaN/AlGaN stacked structure can be reduced by designing the thickness and composition of each nitride semiconductor layer.

Furthermore, according to the FET in the present embodiment, the insulating film 107 is provided below the gate electrode 110, and an MIS structure is adopted. Therefore, it is possible to suppress the current flowing into the gate electrode 110 and apply a positive bias to the gate electrode 110, and an effective structure for a normally-off FET can be realized.

It should be noted that, in the FET in the present embodiment, the first nitride semiconductor layer 103, the second nitride semiconductor layer 104, the third nitride semiconductor layer 105, and the fourth nitride semiconductor layer 106 may include In.

Furthermore, in the FET in the present embodiment, a doping layer may be provided in a part of the first nitride semiconductor layer 103. According to this structure, the amount of charge in the nitride semiconductor layer is controlled, and thus adjusting the threshold voltage of the gate becomes easy.

Furthermore, in the FET in the present embodiment, a different semiconductor layer may be additionally placed above the fourth nitride semiconductor layer 106.

It should be noted that, in the FET in the present embodiment, the first nitride semiconductor layer 103, the second nitride semiconductor layer 104, the third nitride semiconductor layer 105, and the fourth nitride semiconductor layer 106 may be doped with an N-type impurity such as Si and so on.

Furthermore, although in the FET in the present embodiment, the depth of the recess 120 is a depth that penetrates through the third nitride semiconductor layer 105 and the fourth nitride semiconductor layer 106, the depth is not limited to such as long as the distance between the gate electrode 110 and the bulk-side channel can be shortened. For example, the depth of the recess 120 may be a depth that stops midway through the fourth nitride semiconductor layer 106 without reaching the third nitride semiconductor layer 105, or a depth that penetrates through the fourth nitride semiconductor layer 106 and stops midway through the third nitride semiconductor layer 105.

### Embodiment 2

Hereinafter, a configuration of a FET in Embodiment 2 of the present invention and a manufacturing method thereof shall be described.

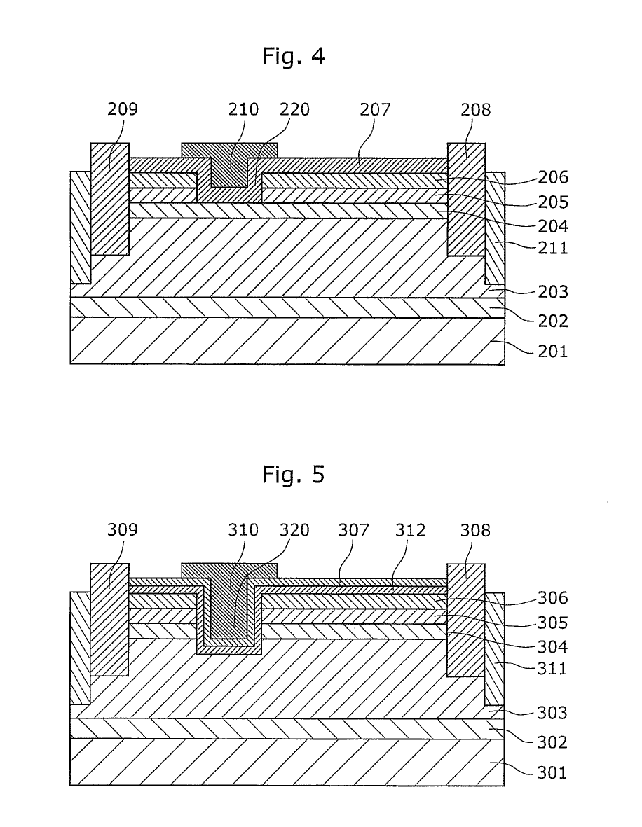

FIG. 4 is a cross-sectional view of a configuration of the FET according to the present embodiment.

The FET includes a substrate 201, a buffer layer 202, a first nitride semiconductor layer 203, a second nitride semiconductor layer 204, a third nitride semiconductor layer 205, a fourth nitride semiconductor layer 206, an insulating film 207, a drain electrode 208, a source electrode 209, a gate electrode 210, and an element separation layer 211.

The substrate 201 is, for example, a sapphire substrate, a SiC substrate, a Si substrate, a GaN substrate, and so on, having a thickness of between 10 μm to 1000 μm, inclusive.

The buffer layer 202 is made of AlN having a thickness, for example, 100 nm, that depends on the substrate 201, and is formed on the substrate 201.

The first nitride semiconductor layer 203 is made of, for example, 2 μm-thick undoped GaN, and is formed on the buffer layer 202.

The second nitride semiconductor layer 204 is formed on the first nitride semiconductor layer 203 and has higher band gap energy than the first nitride semiconductor layer 203. The second nitride semiconductor layer 204 is made of, for example, undoped AlₓGa₁₋ₓN (0<x≦1). For example, the second nitride semiconductor layer 204 is made of 20 nm-thick undoped Al_{0.25}Ga_{0.75}N.

The third nitride semiconductor layer 205 is formed on the second nitride semiconductor layer 204 and has lower band gap energy than the second nitride semiconductor layer 204. The third nitride semiconductor layer 205 is made of, for example, 20 nm-thick undoped GaN.

The fourth nitride semiconductor layer 206 is formed on the third nitride semiconductor layer 205 and has higher band gap energy than the third nitride semiconductor layer 205. The fourth nitride semiconductor layer 206 is made of, for example, undoped Al_{y}Ga_{1-y}N (0<y≦1). For example, the fourth nitride semiconductor layer 206 is made of 25 nm-thick undoped Al_{0.25}Ga_{0.75}N.

A charge of approximately 1×10¹³ cm⁻², for example, is generated in the heterojunction interface between the first nitride semiconductor layer 203 and the second nitride semiconductor layer 204 and in the heterojunction interface between the third nitride semiconductor layer 205 and the fourth nitride semiconductor layer 206 due to spontaneous polarization and piezoelectric polarization, electrons travel through the heterojunction interfaces when the gate is ON, and, in particular, it is possible to significantly reduce resistance in the horizontal direction in the FET.

Here, in order that the electrons of the surface-side channel are more effectively guided to the bulk-side channel, it is preferable that the Al composition ratio of the fourth nitride semiconductor layer 206 be higher than the Al composition ratio of the second nitride semiconductor layer 204, and in addition, it is preferable that the thickness of the fourth nitride semiconductor layer 206 be greater than the thickness of the second nitride semiconductor layer 204. Furthermore, in order to make the film-thickness of the second nitride semiconductor layer 204 directly under the gate electrode 210 thin and realize the normally-off FET, it is preferable that the thickness of the second nitride semiconductor layer 204 be less than the thickness of the fourth nitride semiconductor layer 206.

The drain electrode 208 is formed in a region on one side of the gate electrode 210 and the source electrode 209 is formed in a region on the opposite side of the gate electrode 210. Each of the drain electrode 208 and the source electrode 209 is in contact with the heterojunction interface between the first nitride semiconductor layer 203 and the second nitride semiconductor layer 204 and the heterojunction interface between the third nitride semiconductor layer 205 and the fourth nitride semiconductor layer 206, and is electrically connected to an electron travel region created in the interface regions. The drain electrode 208 and the source electrode 209 are in contact with the first nitride semiconductor layer 203.

The drain electrode 208 and the source electrode 209 are each made of a stacked structure of Ti and Al for example.

A recess 220 is formed in the third nitride semiconductor layer 205 and the fourth nitride semiconductor layer 206. The recess 220 penetrates through the third nitride semiconductor layer 205 and the fourth nitride semiconductor layer 206, that is, penetrates through the heterojunction interface between the third nitride semiconductor layer 205 and the fourth nitride semiconductor layer 206, and reaches the surface of the second nitride semiconductor layer 204. Then, the gate electrode 210 is formed in the recess 220. The recess 220 is formed by selectively performing etching on the third nitride semiconductor layer 205 with respect to the second nitride semiconductor layer 204.

Here, the recess 220 is not formed in the second nitride semiconductor layer 204, and the surface of the second nitride semiconductor layer 204, which serves as the bottom plane of the recess 220, is coplanar with the interface between the second nitride semiconductor layer 204 and the third nitride semiconductor layer 205. With regard to the coplanar referred to here, it is acceptable to have a few nm of etching-precision-related displacement with respect to the surface of the second nitride semiconductor layer 204.

The gate electrode 210 is made of, for example, Pd, Ni, Pt, and so on. It should be noted that the gate electrode 210 may be made of Ti when the material making up the gate electrode 210 does not diffuse into the nitride semiconductor layer due to the insulating film 207.

The insulating film 207 is formed on the bottom plane and lateral planes of the recess 220 and on the surface of the fourth nitride semiconductor layer 206. The insulating film 207 formed on the bottom plane and lateral planes of the recess 220 is interposed between (i) the second nitride semiconductor layer 204, the third nitride semiconductor layer 205, and the fourth nitride semiconductor layer 206, and (ii) the gate electrode 210.

The insulating film 207 is made of, for example, SiN, SiO, AlN, AlO, a stacked structure of SiN and AlN, a stacked structure of SiN and AlO, and so on. When the insulating film 207 is made of SiN or SiO, the insulating film 207 is formed using, for example, a CVD method or a low-pressure CVD method. On the other hand, when the insulating film 207 is made of AlN or AlO, the insulating film 207 is formed using, for example, a sputtering method or an ALD method using an atomic layer deposition apparatus.

The element separation layer 211 is formed, for example, by ion injection of an impurity such as B into a nitride semiconductor layer, and electrically separates the FET from other elements.

As described above, according to the FET in the present embodiment, on-resistance can be reduced due to the same reasons as in the FET in Embodiment 1.

Furthermore, according to the FET in the present embodiment, an effective structure as a normally-off FET can be realized due to the same reasons as in the FET in embodiment 1.

Furthermore, according to the FET in the present embodiment, the recess 220 is formed by selective etching, and the film-thickness of the second nitride semiconductor layer 204 directly under the gate electrode 210 can be controlled accurately. Therefore, therefore adjusting the threshold voltage of the gate becomes easy.

It should be noted that, in the FET in the present embodiment, the first nitride semiconductor layer 203, the second nitride semiconductor layer 204, the third nitride semiconductor layer 205, and the fourth nitride semiconductor layer 206 may include In.

Furthermore, in the FET in the present embodiment, a doping layer may be provided in a part of the first nitride semiconductor layer 203. According to this structure, the amount of charge in the nitride semiconductor layer is controlled, and thus adjusting the threshold voltage of the gate becomes easy.

Furthermore, in the FET in the present embodiment, a different semiconductor layer may be additionally placed above the fourth nitride semiconductor layer 206.

Furthermore, in the FET in the present embodiment, the first nitride semiconductor layer 203, the second nitride semiconductor layer 204, the third nitride semiconductor layer 205, and the fourth nitride semiconductor layer 206 may be doped with an N-type impurity such as Si and so on.

### Embodiment 3

Hereinafter, a configuration of a FET in Embodiment 3 of the present invention and a manufacturing method thereof shall be described.

FIG. 5 is a cross-sectional view of a configuration of the FET according to the present embodiment.

The FET includes a substrate 301, a buffer layer 302, a first nitride semiconductor layer 303, a second nitride semiconductor layer 304, a third nitride semiconductor layer 305, a fourth nitride semiconductor layer 306, an insulating film 307, a drain electrode 308, a source electrode 309, a gate electrode 310, an element separation layer 311, and a fifth nitride semiconductor layer 312.

The substrate 301 is, for example, a sapphire substrate, a SiC substrate, a Si substrate, a GaN substrate, and so on, having a thickness of between 10 μm to 1000 μm, inclusive.

The buffer layer 302 is made of AlN having a thickness, for example, 100 nm, that depends on the substrate 301, and is formed on the substrate 301.

The first nitride semiconductor layer 303 is made of, for example, 2 μm-thick undoped GaN, and is formed on the buffer layer 302.

The second nitride semiconductor layer 304 is formed on the first nitride semiconductor layer 303 and has higher band gap energy than the first nitride semiconductor layer 303. The second nitride semiconductor layer 304 is made of, for example, undoped AlₓGa₁₋ₓN (0<x≦1). For example, the second nitride semiconductor layer 304 is made of 20 nm-thick undoped Al_{0.25}Ga_{0.75}N.

The third nitride semiconductor layer 305 is formed on the second nitride semiconductor layer 304 and has lower band gap energy than the second nitride semiconductor layer 304. The third nitride semiconductor layer 305 is made of, for example, 20 nm-thick undoped GaN.

The fourth nitride semiconductor layer 306 is formed on the third nitride semiconductor layer 305 and has higher band gap energy than the third nitride semiconductor layer 305. The fourth nitride semiconductor layer 306 is made of, for example, undoped Al_{y}Ga_{1-y}N (0<y≦1). For example, the fourth nitride semiconductor layer 306 is made of 25 nm-thick undoped Al_{0.25}Ga_{0.75}N.

A charge of approximately 1×10¹³ cm⁻², for example, is generated in the heterojunction interface between the first nitride semiconductor layer 303 and the second nitride semiconductor layer 304 and in the heterojunction interface between the third nitride semiconductor layer 305 and the fourth nitride semiconductor layer 306 due to spontaneous polarization and piezoelectric polarization, electrons travel through the heterojunction interfaces when the gate is ON, and, in particular, it is possible to significantly reduce resistance in the horizontal direction in the FET.

Here, in order that the electrons of the surface-side channel are more effectively guided to the bulk-side channel, it is preferable that the Al composition ratio of the fourth nitride semiconductor layer 306 be higher than the Al composition ratio of the second nitride semiconductor layer 304 and the fifth nitride semiconductor layer 312, and in addition, it is preferable that the thickness of the fourth nitride semiconductor layer 306 be greater than the thickness of the second nitride semiconductor layer 304 and the fifth nitride semiconductor layer 312. Furthermore, in order to make the film-thickness of the fifth nitride semiconductor layer 312 directly under the gate electrode 310 thin and realize the normally-off FET, it is preferable that the thickness of the fifth nitride semiconductor layer 312 be less than the thickness of the fourth nitride semiconductor layer 306.

The drain electrode 308 is formed in a region on one side of the gate electrode 310 and the source electrode 309 is formed in a region on the opposite side of the gate electrode 310. Each of the drain electrode 308 and the source electrode 309 is in contact with the heterojunction interface between the first nitride semiconductor layer 303 and the second nitride semiconductor layer 304 and the heterojunction interface between the third nitride semiconductor layer 305 and the fourth nitride semiconductor layer 306, and is electrically connected to an electron travel region created in the interface regions. The drain electrode 308 and the source electrode 309 are in contact with the first nitride semiconductor layer 303.

The drain electrode 308 and the source electrode 309 are each made of a stacked structure of Ti and Al for example.

A recess 320 is formed in the first nitride semiconductor layer 303, the second nitride semiconductor layer 304, the third nitride semiconductor layer 305, and the fourth nitride semiconductor layer 306. The recess 320 penetrates through the second nitride semiconductor layer 304, the third nitride semiconductor layer 305, and the fourth nitride semiconductor layer 306, that is, penetrates through the heterojunction interface between the third nitride semiconductor layer 305 and the fourth nitride semiconductor layer 306 and the heterojunction interface between the first nitride semiconductor layer 303 and the second nitride semiconductor layer 304, and reaches the surface of the first nitride semiconductor layer 303. Then, the gate electrode 310 is formed in the recess 320.

The gate electrode 310 is made of, for example, Pd, Ni, Pt, and so on. It should be noted that the gate electrode 310 may be made of Ti when the material making up the gate electrode 310 does not diffuse into the nitride semiconductor layer due to the insulating film 307.

The fifth nitride semiconductor layer 312 is formed on the bottom plane and the lateral planes of the recess 320 and on the surface of the fourth nitride semiconductor layer 306, and is made of, for example, undoped Al_{z}Ga_{1-z}N (0<z≦1). For example, the fifth nitride semiconductor layer 312 is made of 10 nm-thick undoped Al_{0.25}Ga_{0.75}N. The fifth nitride semiconductor layer 312 is formed by epitaxial growing of a nitride semiconductor layer in the recess 320 using a metal-organic chemical vapor deposition (MOCVD) method. The insulating film 307 is formed successively with such epitaxial growing, without being exposed to air (in-situ). The gate electrode 310 is in contact with the insulating film 307 in the recess 320.

Due to the presence of the fifth nitride semiconductor layer 312, the crystallizability of the insulating film 307 can be improved and the insulating film 307 can be formed with excellent reproducibility. Rather than growing the insulating film 307 directly on the nitride semiconductor in the bottom plane of the recess 320, forming the insulating film 307, by successive growing, after forming the fifth nitride semiconductor layer 312 which is an identical nitride semiconductor layer improves the crystallizability and reproducibility of the insulating film 307. Furthermore, a channel layer is formed under the fifth nitride semiconductor layer 312 when the Al composition of the fifth nitride semiconductor layer 312 is higher than the Al composition in the bottom plane of the recess 320, as in the structure in which the fifth nitride semiconductor layer 312 is, for example, an undoped Al_{z}Ga_{1-z}N (0<z≦1) layer and the layer that is in contact with the bottom plane of the recess 320 is, for example, a GaN layer. Since the amount of charge induced at that time is determined according to the film-thickness and composition of the fifth nitride semiconductor layer 312 formed through epitaxial growing which has high controllability, reproducibility can be improved.

The insulating film 307 is formed on the fifth nitride semiconductor layer 312. The insulating film 307 within the recess 320 is formed and interposed between the fifth nitride semiconductor layer 312 and the gate electrode 310.

The insulating film 307 is made of, for example, SiN, SiO, AlN, AlO, a stacked structure of SiN and AlN, a stacked structure of SiN and AlO, and so on, having a thickness of 1 to 5 nm. When the insulating film 307 is made of SiN or SiO, the insulating film 307 is formed using, for example, a CVD method or a low-pressure CVD method. On the other hand, when the insulating film 307 is made of AlN or AlO, the insulating film 307 is formed using, for example, a sputtering method or an ALD method using an atomic layer deposition apparatus.

The element separation layer 311 is formed, for example, by ion injection of an impurity such as B into a nitride semiconductor layer, and electrically separates the FET from other elements.

As described above, according to the FET in the present embodiment, on-resistance can be reduced due to the same reasons as in the FET in Embodiment 1.

Furthermore, according to the FET in the present embodiment, an effective structure as a normally-off FET can be realized due to the same reasons as in the FET in embodiment 1.

Furthermore, according to the FET in the present embodiment, the insulating film 307 can be formed successively with the epitaxial growing of the fifth nitride semiconductor layer 312 within the recess 320, and thus the insulating film 307 having excellent insulation characteristics can be realized.

It should be noted that, in the FET in the present embodiment, the first nitride semiconductor layer 303, the second nitride semiconductor layer 304, the third nitride semiconductor layer 305, and the fourth nitride semiconductor layer 306 may include In.

Furthermore, in the FET in the present embodiment, a doping layer may be provided in a part of the first nitride semiconductor layer 303. According to this structure, the amount of charge in the nitride semiconductor layer is controlled, and thus adjusting the threshold voltage of the gate becomes easy.

Furthermore, in the FET in the present embodiment, a different semiconductor layer may be additionally placed above the fourth nitride semiconductor layer 306.

Furthermore, in the FET in the present embodiment, the first nitride semiconductor layer 303, the second nitride semiconductor layer 304, the third nitride semiconductor layer 305, the fourth nitride semiconductor layer 306, and the fifth nitride semiconductor layer 312 may be doped with an N-type impurity such as Si and so on.

Furthermore, although in the FET in the present embodiment, the depth of the recess 320 is a depth that penetrates through the second nitride semiconductor layer 304, the third nitride semiconductor layer 305, and the fourth nitride semiconductor layer 306, the depth is not limited to such as long as the distance between the gate electrode 310 and the bulk-side channel can be shortened. For example, the depth of the recess 320 may be a depth that stops midway through the fourth nitride semiconductor layer 306 without reaching the third nitride semiconductor layer 305, a depth that penetrates through the fourth nitride semiconductor layer 306 and stops midway through the third nitride semiconductor layer 305, or a depth that penetrates through the fourth nitride semiconductor layer 306 and the third nitride semiconductor layer 305 and stops midway through the second nitride semiconductor layer 304.

### Embodiment 4

Hereinafter, a configuration of a FET in Embodiment 4 of the present invention and a manufacturing method thereof shall be described.

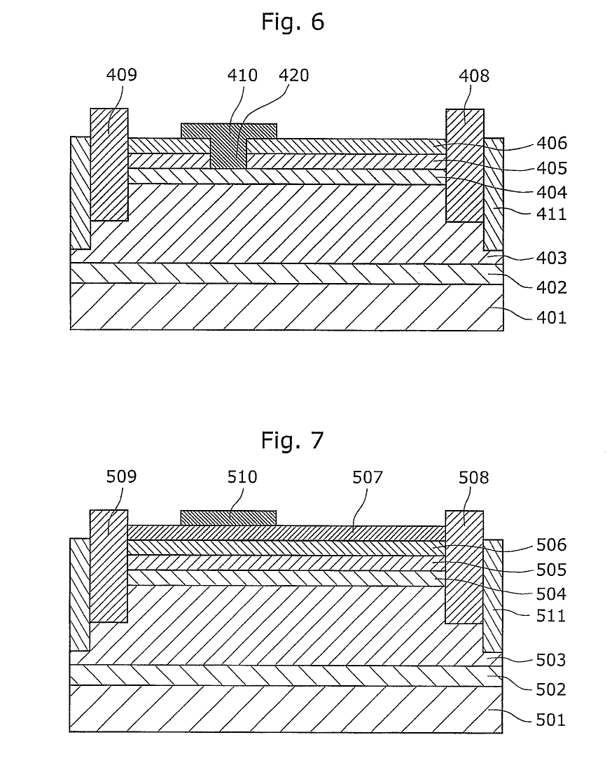

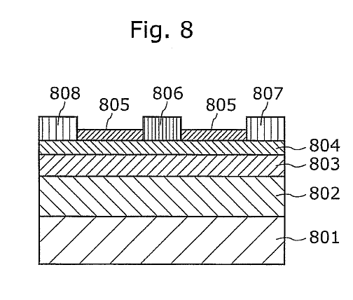

FIG. 6 is a cross-sectional view of a configuration of the FET according to the present embodiment.

The FET includes a substrate 401, a buffer layer 402, a first nitride semiconductor layer 403, a second nitride semiconductor layer 404, a third nitride semiconductor layer 405, a fourth nitride semiconductor layer 406, a drain electrode 408, a source electrode 409, a gate electrode 410, and an element separation layer 411.

The substrate 401 is, for example, a sapphire substrate, a SiC substrate, a Si substrate, a GaN substrate, and so on, having a thickness of between 10 μm to 1000 μm, inclusive.

The buffer layer 402 is made of AlN having a thickness, for example, 100 nm, that depends on the substrate 401, and is formed on the substrate 401.

The first nitride semiconductor layer 403 is made of, for example, 2 μm-thick undoped GaN, and is formed on the buffer layer 402.

The second nitride semiconductor layer 404 is formed on the first nitride semiconductor layer 403 and has higher band gap energy than the first nitride semiconductor layer 403. The second nitride semiconductor layer 404 is made of, for example, undoped AlₓGa₁₋ₓN (0<x≦1). For example, the second nitride semiconductor layer 404 is made of 30 nm-thick undoped Al_{0.25}Ga_{0.75}N.

The third nitride semiconductor layer 405 is formed on the second nitride semiconductor layer 404 and has lower band gap energy than the second nitride semiconductor layer 404. The third nitride semiconductor layer 405 is made of, for example, 30 nm-thick undoped GaN.

The fourth nitride semiconductor layer 406 is formed on the third nitride semiconductor layer 405 and has higher band gap energy than the third nitride semiconductor layer 405. The fourth nitride semiconductor layer 406 is made of, for example, undoped Al_{y}Ga_{1-y}N (0<y≦1). For example, the fourth nitride semiconductor layer 406 is made of 30 nm-thick undoped Al_{0.25}Ga_{0.75}N. A charge of approximately 1×10¹³ cm⁻², for example, is generated in the heterojunction interface between the first nitride semiconductor layer 403 and the second nitride semiconductor layer 404 and in the heterojunction interface between the third nitride semiconductor layer 405 and the fourth nitride semiconductor layer 406 due to spontaneous polarization and piezoelectric polarization, electrons travel through the heterojunction interfaces when the gate is ON, and, in particular, it is possible to significantly reduce resistance in the horizontal direction in the FET.

Here, in order that the electrons of the surface-side channel are more effectively guided to the bulk-side channel, it is preferable that the Al composition ratio of the fourth nitride semiconductor layer 406 be higher than the Al composition ratio of the second nitride semiconductor layer 404, and in addition, it is preferable that the thickness of the fourth nitride semiconductor layer 406 be greater than the thickness of the second nitride semiconductor layer 404.

The drain electrode 408 is formed in a region on one side of the gate electrode 410 and the source electrode 409 is formed in a region on the opposite side of the gate electrode 410. Each of the drain electrode 408 and the source electrode 409 is in contact with the heterojunction interface between the first nitride semiconductor layer 403 and the second nitride semiconductor layer 404 and the heterojunction interface between the third nitride semiconductor layer 405 and the fourth nitride semiconductor layer 406, and is electrically connected to an electron travel region created in the interface regions. The drain electrode 408 and the source electrode 409 are in contact with the first nitride semiconductor layer 403.

The drain electrode 408 and the source electrode 409 are each made of a stacked structure of Ti and Al for example.

A recess 420 is formed in the third nitride semiconductor layer 405 and the fourth nitride semiconductor layer 406. The recess 420 penetrates through the third nitride semiconductor layer 405 and the fourth nitride semiconductor layer 406, that is, penetrates through the heterojunction interface between the third nitride semiconductor layer 405 and the fourth nitride semiconductor layer 406, and reaches the surface of the second nitride semiconductor layer 404. Then, the gate electrode 410 is formed in the recess 320 to cover the bottom plane and the lateral planes of the recess 420. Therefore, the gate electrode 410 within the recess 420 is in contact with the second nitride semiconductor layer 404, the third nitride semiconductor layer 405, and the fourth nitride semiconductor layer 406 directly, without mediation by an insulating layer. The recess 420 is formed by selectively performing etching on the third nitride semiconductor layer 405 with respect to the second nitride semiconductor layer 404.

Here, the recess 420 is not formed in the second nitride semiconductor layer 404, and the surface of the second nitride semiconductor layer 404, which serves as the bottom plane of the recess 420, is coplanar with the interface between the second nitride semiconductor layer 404 and the third nitride semiconductor layer 405.

The gate electrode 410 forms a schottky junction with the second nitride semiconductor layer 404, the third nitride semiconductor layer 405, and the fourth nitride semiconductor layer 406, and is made of, for example, Pd, Ni, Pt, and so on.

The element separation layer 411 is formed, for example, by ion injection of an impurity such as B into a nitride semiconductor layer, and electrically separates the FET from other elements.

As described above, according to the FET in the present embodiment, on-resistance can be reduced due to the same reasons as in the FET in Embodiment 1.

It should be noted that, in the FET in the present embodiment, the first nitride semiconductor layer 403, the second nitride semiconductor layer 404, the third nitride semiconductor layer 405, and the fourth nitride semiconductor layer 406 may include In.

Furthermore, in the FET in the present embodiment, a doping layer may be provided in a part of the first nitride semiconductor layer 403. According to this structure, the amount of charge in the nitride semiconductor layer is controlled, and thus adjusting the threshold voltage of the gate becomes easy.

Furthermore, in the FET in the present embodiment, a different semiconductor layer may be additionally placed above the fourth nitride semiconductor layer 406.

Furthermore, in the FET in the present embodiment, the first nitride semiconductor layer 403, the second nitride semiconductor layer 404, the third nitride semiconductor layer 405, and the fourth nitride semiconductor layer 406 may be doped with an N-type impurity such as Si and so on.

Furthermore, although in the FET in the present embodiment, the depth of the recess 420 is a depth that penetrates through the third nitride semiconductor layer 405 and the fourth nitride semiconductor layer 406, the depth is not limited to such as long as the distance between the gate electrode 410 and the bulk-side channel can be shortened. For example, the depth of the recess 420 may be a depth that stops midway through the fourth nitride semiconductor layer 406 without reaching the third nitride semiconductor layer 405, or a depth that penetrates through the fourth nitride semiconductor layer 406 and stops midway through the third nitride semiconductor layer 405.

### Embodiment 5

Hereinafter, a configuration of a FET in Embodiment 5 of the present invention and a manufacturing method thereof shall be described.

FIG. 7 is a cross-sectional view of a configuration of the FET according to the present embodiment.

The FET includes a substrate 501, a buffer layer 502, a first nitride semiconductor layer 503, a second nitride semiconductor layer 504, a third nitride semiconductor layer 505, a fourth nitride semiconductor layer 506, an insulating film 507, a drain electrode 508, a source electrode 509, a gate electrode 510, and an element separation layer 511.

The substrate 501 is, for example, a sapphire substrate, a SiC substrate, a Si substrate, a GaN substrate, and so on, having a thickness of between 10 μm to 1000 μm, inclusive.

The buffer layer 502 is made of AlN having a thickness, for example, 100 nm, that depends on the substrate 501, and is formed on the substrate 501.

The first nitride semiconductor layer 503 is made of, for example, 2 μm-thick undoped GaN, and is formed on the buffer layer 502.

The second nitride semiconductor layer 504 is formed on the first nitride semiconductor layer 503 and has higher band gap energy than the first nitride semiconductor layer 503. The second nitride semiconductor layer 504 is made of, for example, undoped AlₓGa₁₋ₓN (0<x≦1). For example, the second nitride semiconductor layer 504 is made of 20 nm-thick undoped Al_{0.25}Ga_{0.75}N.

The third nitride semiconductor layer 505 is formed on the second nitride semiconductor layer 504 and has lower band gap energy than the second nitride semiconductor layer 504. The third nitride semiconductor layer 505 is made of, for example, 20 nm-thick undoped GaN.

The fourth nitride semiconductor layer 506 is formed on the third nitride semiconductor layer 505 and has higher band gap energy than the third nitride semiconductor layer 505. The fourth nitride semiconductor layer 506 is made of, for example, undoped Al_{y}Ga_{1-y}N (0<y≦1). For example, the fourth nitride semiconductor layer 506 is made of 25 nm-thick undoped Al_{0.25}Ga_{0.75}N.

A charge of approximately 1×10¹³ cm⁻², for example, is generated in the heterojunction interface between the first nitride semiconductor layer 503 and the second nitride semiconductor layer 504 and in the heterojunction interface between the third nitride semiconductor layer 505 and the fourth nitride semiconductor layer 506 due to spontaneous polarization and piezoelectric polarization, electrons travel through the heterojunction interfaces when the gate is ON, and, in particular, it is possible to significantly reduce resistance in the horizontal direction in the FET.

Here, in order that the electrons of the surface-side channel are more effectively guided to the bulk-side channel, it is preferable that the Al composition ratio of the fourth nitride semiconductor layer 506 be higher than the Al composition ratio of the second nitride semiconductor layer 504, and in addition, it is preferable that the thickness of the fourth nitride semiconductor layer 506 be greater than the thickness of the second nitride semiconductor layer 504. Furthermore, in order to make the film-thickness of the second nitride semiconductor layer 504 directly under the gate electrode 510 thin and realize the normally-off FET, it is preferable that the thickness of the second nitride semiconductor layer 504 be less than the thickness of the fourth nitride semiconductor layer 506.

The drain electrode 508 is formed in a region on one side of the gate electrode 510 and the source electrode 509 is formed in a region on the opposite side of the gate electrode 510. Each of the drain electrode 508 and the source electrode 509 is in contact with the heterojunction interface between the first nitride semiconductor layer 503 and the second nitride semiconductor layer 504 and the heterojunction interface between the third nitride semiconductor layer 505 and the fourth nitride semiconductor layer 506, and is electrically connected to an electron travel region created in the interface regions. The drain electrode 508 and the source electrode 509 are in contact with the first nitride semiconductor layer 503.

The drain electrode 508 and the source electrode 509 are each made of a stacked structure of Ti and Al for example.

The insulating film 507 is formed on the surface of the fourth nitride semiconductor layer 506, and is made of, for example, SiN, SiO, AlN, AlO, a stacked structure of SiN and AlN, a stacked structure of SiN and AlO, and so on. When the insulating film 507 is made of SiN or SiO, the insulating film 507 is formed using, for example, a CVD method or a low-pressure CVD method. On the other hand, when the insulating film 507 is made of AlN or AlO, the insulating film 507 is formed using, for example, a sputtering method or an ALD method using an atomic layer deposition apparatus.

The gate electrode 510 is formed on the insulating film 507, and is made of, for example, Pd, Ni, Pt, and so on. It should be noted that the gate electrode 510 may be made of Ti when the material making up the gate electrode 510 does not diffuse into the nitride semiconductor layer due to the insulating film 507.

The element separation layer 511 is formed, for example, by ion injection of an impurity such as B into a nitride semiconductor layer, and electrically separates the FET from other elements.

As described above, according to the FET in the present embodiment, on-resistance can be reduced due to the same reasons as in the FET in Embodiment 1.

Furthermore, according to the FET in the present embodiment, an effective structure as a normally-off FET can be realized due to the same reasons as in the FET in embodiment 1.

It should be noted that, in the FET in the present embodiment, the first nitride semiconductor layer 503, the second nitride semiconductor layer 504, the third nitride semiconductor layer 505, and the fourth nitride semiconductor layer 506 may include In.

Furthermore, in the FET in the present embodiment, a doping layer may be provided in a part of the first nitride semiconductor layer 503. According to this structure, the amount of charge in the nitride semiconductor layer is controlled, and thus adjusting the threshold voltage of the gate becomes easy.

Furthermore, in the FET in the present embodiment, a different semiconductor layer may be additionally placed above the fourth nitride semiconductor layer 506.

Furthermore, in the FET in the present embodiment, the first nitride semiconductor layer 503, the second nitride semiconductor layer 504, the third nitride semiconductor layer 505, and the fourth nitride semiconductor layer 506 may be doped with an N-type impurity such as Si and so on.

Furthermore, in the same manner as in the FET in Embodiment 3, the FET in the present embodiment may adopt the form of a schottky junction FET in which the insulating film 507 is not provided.

Although FETs according to the present invention have been described based on the embodiments, the present invention is not limited to such embodiments. Various modifications that may be conceived by those skilled in the art which do not depart from the essence of the present invention are intended to be included within the scope of the present invention.

### INDUSTRIAL APPLICABILITY

The present invention can be applied to FETs, and can be applied particularly to a high-power radio frequency device in a cellular phone base station, and so on, and to a high-power switching device in an inverter, and so on, among others.

What is claimed is:

1. A field-effect transistor, comprising:
a first nitride semiconductor layer;
a second nitride semiconductor layer formed on said first nitride semiconductor layer and having a band gap energy that is higher than a band gap energy of said first nitride semiconductor layer;
a third nitride semiconductor layer formed on said second nitride semiconductor layer; and
a fourth nitride semiconductor layer formed on said third nitride semiconductor layer and having a band gap energy that is higher than a band gap energy of said third nitride semiconductor layer,
wherein a channel is formed in a heterojunction interface between said first nitride semiconductor layer and said second nitride semiconductor layer.

2. The field-effect transistor according to claim 1,
wherein a gate electrode of said field-effect transistor is formed in a recess provided in said fourth nitride semiconductor layer.

3. The field-effect transistor according to claim 2,
wherein said recess penetrates through a heterojunction interface between said third nitride semiconductor layer and said fourth nitride semiconductor layer.

4. The field-effect transistor according to claim 3,
wherein said recess penetrates through the heterojunction interface between said third nitride semiconductor layer and said fourth nitride semiconductor layer, and reaches a surface of said second nitride semiconductor layer, and
the surface of said second nitride semiconductor layer, which is a bottom plane of said recess, is coplanar with as the heterojunction interface between said second nitride semiconductor layer and said third nitride semiconductor layer.

5. The field-effect transistor according to claim 4,
wherein said recess penetrates through said second nitride semiconductor layer, said third nitride semiconductor layer, and said fourth nitride semiconductor layer, and reaches said first nitride semiconductor layer.

6. The field-effect transistor according to claim 2, further comprising
an insulating film formed on a bottom plane of said recess.

7. The field-effect transistor according to claim 2, further comprises:
a fifth nitride semiconductor layer formed on a bottom plane of said recess; and
an insulating film formed between said gate electrode and said fifth nitride semiconductor layer.

8. The field-effect transistor according to claim 7,
wherein said fifth nitride semiconductor layer is made of Al_{z}Ga_{1-z}N, where 0<z≦1.

9. The field-effect transistor according to claim 6,
wherein said insulating film is made of silicon nitride.

10. The field-effect transistor according to claim 6,
wherein said insulating film is configured of a stacked structure of silicon nitride and aluminum nitride.

11. The field-effect transistor according to claim 6,
wherein said insulating film is formed using an atomic layer deposition apparatus.

12. The field-effect transistor according to claim 1,
wherein a film-thickness of said second nitride semiconductor layer is less than a film-thickness of said fourth nitride semiconductor layer.

13. The field-effect transistor according to claim 1,
wherein each of a source electrode and a drain electrode of said field-effect transistor is in contact with the heterojunction interface between said first nitride semiconductor layer and said second nitride semiconductor layer and a heterojunction interface between said third nitride semiconductor layer and said fourth nitride semiconductor layer.

14. The field-effect transistor according to claim 1,
wherein said first nitride semiconductor layer is made of GaN,
said second nitride semiconductor layer is made of AlₓGa₁₋ₓN, where 0<x≦1,
said third nitride semiconductor layer is made of GaN, and
said fourth nitride semiconductor layer is made of Al_{y}Ga_{1-y}N, where 0<y≦1.
